(19) United States
(12) Patent Application Publication
(10) Pub. No.: US 2025/0218998 A1
(43) Pub. Date: Jul. 3, 2025

(54) LOW TEMPERATURE SOLDER INTERCONNECT FOR PACKAGE PITCH SCALING

(71) Applicant: Intel Corporation, Santa Clara, CA (US)

(72) Inventors: Bohan SHAN, Chandler, AZ (US); Shripad GOKHALE, Gilbert, AZ (US); Rui ZHANG, Chandler, AZ (US); Mine KAYA, Scottsdale, AZ (US); Haobo CHEN, Chandler, AZ (US); Steve S. CHO, Chandler, AZ (US); Timothy GOSSELIN, Phoenix, AZ (US); Kartik SRINIVASAN, Gilbert, AZ (US); Edvin CETEGEN, Chandler, AZ (US); Kyle ARRINGTON, Gilbert, AZ (US); Nicholas S. HAEHN, Scottsdale, AZ (US); Ryan CARRAZZONE, Chandler, AZ (US); Hongxia FENG, Chandler, AZ (US); Srinivas Venkata Ramanuja PIETAMBARAM, Chandler, AZ (US); Gang DUAN, Chandler, AZ (US); Ashay DANI, Chandler, AZ (US); Yoshihiro TOMITA, Tsukuba-shi (JP); Ziyin LIN, Chandler, AZ (US); Yiqun BAI, Chandler, AZ (US); Jose WAIMIN, Gilbert, AZ (US); Dingying David XU, Chandler, AZ (US); Bin MU, Tempe, AZ (US); Mohit GUPTA, Chandler, AZ (US); Jeremy D. ECTON, Gilbert, AZ (US); Brandon C. MARIN, Gilbert, AZ (US); Xiaoying GUO, Chandler, AZ (US); Jung Kyu HAN, Chandler, AZ (US); Liang HE, Chandler, AZ (US)

(21) Appl. No.: 18/400,380

(22) Filed: Dec. 29, 2023

(51) Int. Cl. H01L 23/00; H01L 23/13; H01L 23/498; H01L 23/538; H01R 4/58; H01R 12/57; H01R 43/02; H05K 3/36

(52) U.S. Cl. CPC H01L 24/14; H01L 21/4846; H01L 23/49811; H01L 23/49816; H01L 23/49866; H01L 24/13; H01L 24/16; H01L 24/81; H01R 4/58; H01R 43/02; H05K 3/368; H01L 2224/13109; H01L 2224/13111; H01L 2224/13113; H01L 2224/1312; H01L 2224/13139; H01L 2224/13144; H01L 2224/13147; H01L 2224/13155; H01L 2224/1316; H01L 2224/13164; H01L 2224/13169; H01L 2224/14133; H01L 2224/14179; H01L 2224/14505; H01L 2224/16145; H01L 2224/16227; H01L 2224/81193; H01L 2224/81203; H01L 2224/81815; H05K 2203/047

(57) ABSTRACT

Embodiments disclosed herein include an apparatus that comprises a first substrate and a second substrate over the first substrate. In an embodiment, an array of interconnects is provided between the first substrate and the second substrate. The array of interconnects comprises a first interconnect with a first material composition, and a second interconnect with a second material composition that is different than the first material composition.

### BACKGROUND

In advanced packaging solutions, bridge dies are often used in order to communicatively couple two or more chiplets together. However, the die bonding of the embedded bridge die to the substrate can be challenging due to large heat dissipation through the substrate with many stacked vias. Particularly, corner joints have a higher risk of defect formation than center locations due to the heat distribution. That is, the thermal energy at the corner regions may be lower than the center, and the solder interconnects may not properly reflow.

Further, first level interconnect (FLI) bonding with large dies and/or tighter embedded bridge pitches may lead to reduced thermocompression bonding (TCB) process windows. Expansion in the Z-direction during bonding may further reduce the process window. Increasing pedestal and/or substrate temperature can be a potential solution. However, this approach is limited by flux and process considerations. That is, flux activation temperature, dry out, and the like are considerations that need to be accounted for.

For pitch scaling, a smaller bump pitch will also significantly amplify the local warpage or undulation impact on forming a quality joint. For example, when the bump becomes smaller, the bump height will also reduce. Therefore, if there is a local undulation or warpage caused height variation, a joint opening or an extra solder extrusion can occur.

### BRIEF DESCRIPTION OF THE DRAWINGS

FIGS. 1A-1C are cross-sectional illustrations depicting a thermocompression bonding (TCB) process between a first substrate and a second substrate with local undulation, in accordance with an embodiment.

FIGS. 2A-2C are cross-sectional illustrations depicting a TCB process between a first substrate and a second substrate with local undulation that uses a first solder and a second solder, in accordance with an embodiment.

FIG. 3 is a plan view illustration of a substrate with an array of bumps that includes first solder interconnects and second solder interconnects, in accordance with an embodiment.

FIG. 4A is a cross-sectional illustration of a TCB process between a first substrate and a second substrate with a single type of solder, in accordance with an embodiment.

FIG. 4B is a plan view illustration of a heat map of the TCB process indicating that the corner regions receive less heat than the center region, in accordance with an embodiment.

FIG. 4C is a plan view illustration of a substrate with an array of bumps that includes first solder interconnects and second solder interconnects at the corner regions, in accordance with an embodiment.

FIGS. 5A-5F are cross-sectional illustrations depicting a process for fabricating a package substrate with first level interconnects (FLIs) that have a first type of solder and a second type of solder, in accordance with an embodiment.

FIG. 6A is a cross-sectional illustration of an electronic system that includes a bridge that is coupled to the package substrate through a first type of solder and a second type of solder, in accordance with an embodiment.

FIG. 6B is a cross-sectional illustration of an electronic system that includes FLIs with a first type of solder and a second type of solder, in accordance with an embodiment.

FIG. 6C is a cross-sectional illustration of an electronic system that includes second level interconnects (SLIs) with a first type of solder and second type of solder, in accordance with an embodiment.

FIG. 7 is a schematic of a computing device built in accordance with an embodiment.

### EMBODIMENTS OF THE PRESENT DISCLOSURE

Described herein are electronic systems, and more particularly, architectures for low temperature solder architectures that are selectively placed in order to improve reliability and performance, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, advanced semiconductor packaging solutions are trending towards the use of chiplet architectures. Chiplet solutions are enabled through the use of bridge structures. The bridge structure incorporates fine trace widths and high density routing in order to provide a large number of connections between the overlying chiplets. This leads to small pitch interconnects. Accordingly, the attachment of the chiplets to the package substrate is increased in complexity due to the decrease in interconnect pitch. For example, as pitch decreases the process window for thermocompression bonding (TCB) shrinks.

One issue that arise in such architectures is substrate surface undulation. In the case of organic substrate surfaces, such as the surface of the package substrate, the surface is typically not perfectly flat. This produces variations in the height of the interconnects. During TCB processes, this can lead to interconnect cracking and open circuits. Another issue is thermal uniformity during the TCB process. Typically, the central region of the bump field will experience a higher heat flux than the corner regions of the bump field. As such, the corners may not reflow properly. Alternatively, the heat of the TCB process is increased to account for the corner regions. This can create problems relating to thermal expansion and the like.

In some instances, the interconnects of interest are those between the bridge and the package substrate. For example, a bridge with vias may connect to a surface of the package substrate at a bottom of a cavity into the package substrate. In other instances, the interconnects of interest are those between the chiplets and the package substrate, which are sometimes referred to as first level interconnects (FLIs). In yet another instance, the interconnects of interest are those between the board and the package substrate, which are sometimes referred to as second level interconnects (SLIs).

In order to accommodate the issues described above, embodiments disclosed herein may include bump fields with two or more different interconnect types. Bump fields may refer to an array of interconnects that are provided between a first substrate and a second substrate. The interconnects may include solder bumps. In some embodiments, the different interconnect types may refer to interconnects that have different material compositions. The different material compositions may allow for different melting temperatures (or different reflow temperatures).

The different melting temperatures may enable improved TCB processes. For example, in the case of undulating surfaces, low temperature solder can be provided at low points on the substrate. During retraction of the TCB head, the low temperature solder remains liquid longer, and can stretch to accommodate a taller interconnect height without cracking. As such, open circuits are avoided. Low temperature solder can also be provided at corner regions of the bump field. The lower temperatures experienced at the corners may still be sufficient to melt or reflow the low temperature solder. As such, the overall TCB temperature does not need to be increased in order to provide high yielding structures.

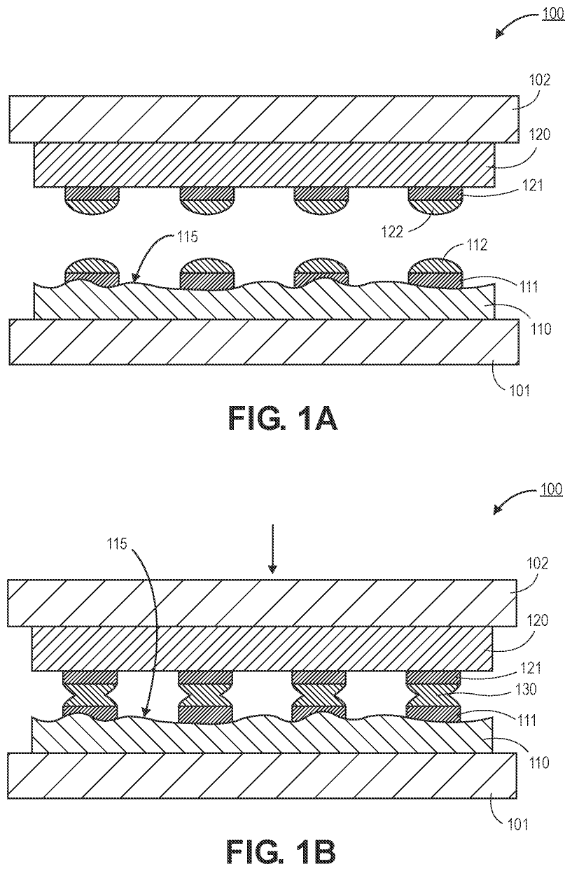

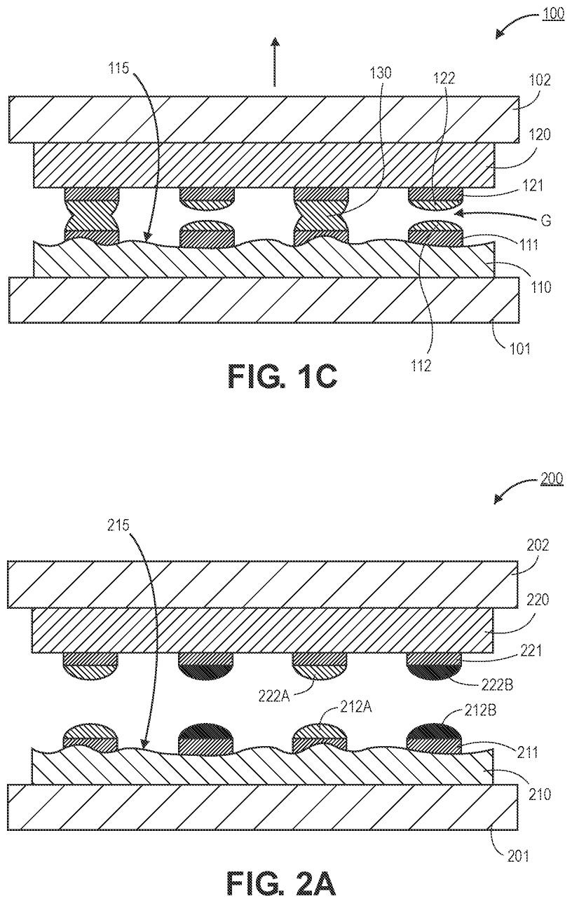

Referring now to FIGS. 1A-1C, a series of cross-sectional illustrations depicting a TCB process between a first substrate 110 and a second substrate 120 is shown, in accordance with an embodiment. In the embodiment shown in FIGS. 1A-1C, the solder 112/122 is uniform across the bump field.

Referring now to FIG. 1A, a cross-sectional illustration of a device 100 is shown, in accordance with an embodiment. In an embodiment, the device 100 includes a pedestal 101 and a bonding head 102. A first substrate 110 may be provided on the pedestal 101, and a second substrate 120 may be attached to the bonding head 102. The first substrate 110 and the second substrate 120 may be any type of substrates. For example, the first substrate 110 and the second substrate 120 may be a package substrate, a board, a die, a bridge die, or the like. More detailed descriptions of various substrate architectures are provided in greater detail below.

In an particular embodiment, the first substrate 110 may have a top surface 115 that faces away from the pedestal 101. The top surface 115 may have a non-planar surface. That is, the top surface 115 may have undulation. As a result, the pads 111 on the first substrate 110 may be provided at different Z-heights from each other. The undulating top surface 115 may be the result of the substrate type and/or methods used to form the first substrate 110. For example, organic buildup films that are laminated together may result in some degree of undulation, as shown in FIG. 1A.

In an embodiment, pads 121 may be provided on the second substrate 120 opposite from the pads 111. The pads 121 may be at substantially the same Z-height as each other. For example, the second substrate 120 may have a substantially planar surface. This may occur when the second substrate 120 is a silicon die, a ceramic substrate, a glass substrate, or the like. Though, in some embodiments, the second substrate 120 may also have a non-planar (e.g., undulating) surface similar to the top surface 115 of the first substrate 110.

In an embodiment, solder 112 may be provided on the pads 111, and solder 122 may be provided on the pads 121. The solder 112 and the solder 122 may be the same material composition. Additionally, fluxing material (not shown) or the like may be provided over and/or in the solder 112 and the solder 122. While solder 112 and solder 122 are shown on both pads 111 and 121, it is to be appreciated that solder 112 or 122 may be provided on either pads 111 or pads 121.

Referring now to FIG. 1B, a cross-sectional illustration of the device 100 after the bonding head 102 is brought down towards the pedestal 101 (as indicated by the arrow) is shown, in accordance with an embodiment. As the bonding head 102 and the pedestal 101 are brought together, energy may be applied to one or both of the bonding head 102 and the pedestal 101 in order to heat up the first substrate 110 and/or the second substrate 120. The increase in temperature may result in the solder 112 and the solder 122 reflowing. As the two solders 112 and 122 are brought together, they form a joint 130 between the pad 111 and the pad 121. At this point, the joint 130 may still be in a liquid phase. That is, the joint 130 is compliable.

Referring now to FIG. 1C, a cross-sectional illustration of the device 100 after the bonding head 102 is retracted from the pedestal 101 (as indicated by the arrow) is shown, in accordance with an embodiment. As the bonding head 102 is retracted, the energy applied to the bonding head 102 and/or the pedestal 101 is reduced or stopped. As such, the joint 130 is allowed to solidify. This creates issues because some of the joints 130 require a larger standoff height to account for the undulation of the top surface 115 of the first substrate 110. For example, (from left to right) the second and fourth joints 130 are at depressions. As such, the joints 130 may crack or break so that there is a gap G between solder 112 and solder 122. This can result in an open circuit between the first substrate 110 and the second substrate 120, and lead to a defective device 100.

Accordingly, embodiments disclosed herein include a multi-solder solution that enables improved connections between substrates, even when there is undulation. Particularly, a first solder with a first melting temperature is provided at first locations and a second solder with a second melting temperature (that is lower than the first melting temperature) is provided at second locations. The second locations may be provided at depressions along the first substrate. As such, during retraction of the bonding head, the joints at the second locations remain liquid longer, and can accommodate the larger standoff height without cracking or fracturing.

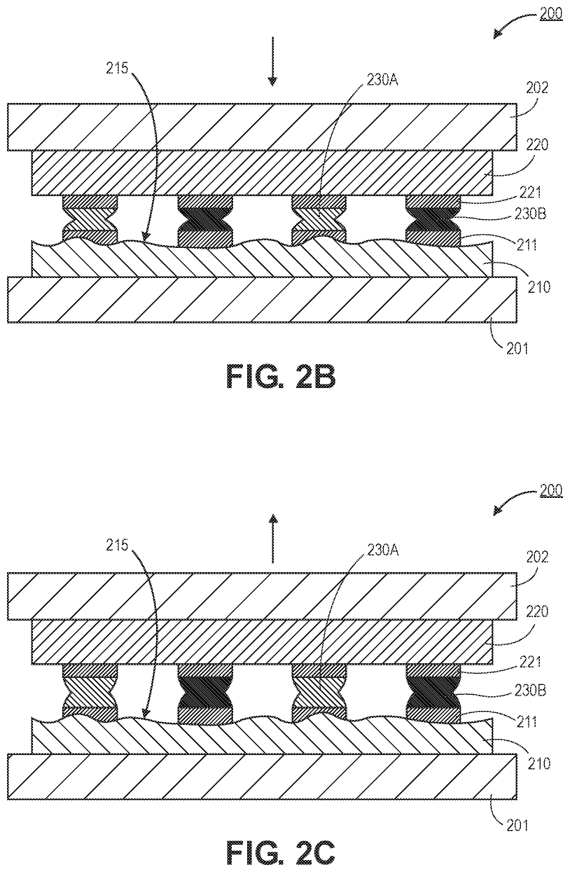

Referring now to FIGS. 2A-2C, a series of cross-sectional illustrations depicting a process for bonding a first substrate 210 to a second substrate 220 with a hybrid bump field is shown, in accordance with an embodiment. In an embodiment, the hybrid bump field includes first solder 212A/222A and second solder 212B/222B. The different solders have different compositions that lead to different melting temperatures.

Referring now to FIG. 2A, a cross-sectional illustration of a device 200 is shown, in accordance with an embodiment. In an embodiment, the device 200 includes a pedestal 201 and a bonding head 202. A first substrate 210 is provided on the pedestal 201, and a second substrate 220 is attached to the bonding head 202. The first substrate 210 and the second substrate 220 may include any type of substrates, such as, but not limited to, a package substrate, a board, a bridge die, a die, a chiplet, or the like. In an embodiment, a top surface 215 of the first substrate 210 may be non-planar. That is, the top surface 215 may be undulating in some instances.

In an embodiment, pads 211 may be provided on the top surface 215 of the first substrate 210. Similarly, pads 221 may be provided on the second substrate 220 opposite from the pads 211. In an embodiment, the pads 211 may be covered by solder. The solder may include a first solder 212A and a second solder 212B. The first solder 212A may be provided over pads 211 that are at a higher Z-position than pads 211 with the second solder 212B. In an embodiment, the second solder 212B may have a composition that allows for a lower melting temperature than the first solder 212A. Similarly, first solder 222A may be provided opposite the first solder 212A, and second solder 222B may be provided opposite the second solder 212B.

In an embodiment, the first solder 212A and the second solder 212B may both be any suitable solder compositions that provide the necessary melting points. In general, the solders described herein may be tin-based solders with any suitable alloying elements. For example, any of the solders described herein may comprise one or more of tin, copper, nickel, iron, indium, antimony, bismuth, silver, gold, palladium, or platinum. In some embodiments, the first solder 212A and the second solder 212B may comprise the same elemental constituents with different alloying percentages. In other embodiments, the first solder 212A and the second solder 212B may comprise different elemental constituents. In some embodiments, the first solder 212A may have a melting temperature that is approximately 300° C. or higher, and the second solder 212B may have a melting temperature that is approximately 300° C. or lower.

Referring now to FIG. 2B, a cross-sectional illustration of the device 200 after the bonding head 202 is brought down towards the pedestal 201 (as indicated by the arrow) is shown, in accordance with an embodiment. As the bonding head 202 and the pedestal 201 are brought together, energy may be applied to one or both of the bonding head 202 and the pedestal 201 in order to heat up the first substrate 210 and/or the second substrate 220. The increase in temperature may result in the solder 212A/212B and the solder 222A/222B reflowing. As the two sides are brought together, the solders form joints 230A and 230B between the pads 211 and the pads 221. At this point, the joints 230A and 230B may still be in a liquid phase. That is, the joints 230A and 230B are compliable.

Referring now to FIG. 2C, a cross-sectional illustration of the device 200 after the bonding head 202 is retracted from the pedestal 201 (as indicated by the arrow) is shown, in accordance with an embodiment. As the bonding head 202 is retracted, the energy applied to the bonding head 202 and/or the pedestal 201 is reduced or stopped. As such, the joints 230A are allowed to solidify. However, since the joints 230B have a lower melting point, the joints 230B may remain liquid and compliable. With continued retraction of the bonding head 202, the joints 230B may continue to expand in the Z-direction. As such, larger distances between the first substrate 210 and the second substrate 220 that are caused by the undulation of the top surface 215 can be accommodated. That is, the joints 230B may have a larger height than the joints 230A. Further, the longer period in the liquid phase allows for joints 230B to expand without the potential of cracking or other damage. As such, improved yield is provided.

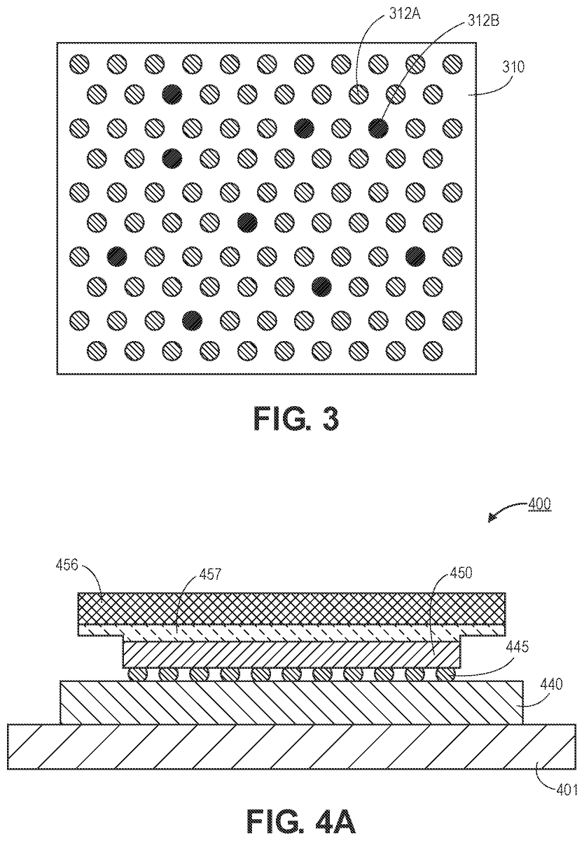

As can be appreciated in FIGS. 2A-2C, the ability to locate areas where the top surface 215 is depressed is needed in order to insert the low melting point solders. For example, metrology that analyzes the top surface 215 can be used to identify regions with localized depressions where the low melting point solder is desired. An example of such a bump field is shown in FIG. 3.

Referring now to FIG. 3, a plan view illustration of a substrate 310 is shown, in accordance with an embodiment. The substrate 310 may be any type of substrate that is used in the assembly of an electronic system. For example, the substrate 310 may be a board, a package substrate, a bridge die, a die, or the like. In an embodiment a bump field may be provided across the surface of the substrate 310. The bump field 310 may include an array of interconnects 312. The interconnects 312 may be provided in any pattern or layout, and there may be any number of interconnects 312 over the substrate 310. In a particular embodiment, the interconnects 312 may comprise solder bumps.

In an embodiment, the bump field may include at least first interconnects 312A and one or more second interconnects 312B. The first interconnects 312A may have a first solder composition and the second interconnects 312B may have a second solder composition. In an embodiment, the second solder composition may have a melting temperature that is lower than a melting temperature of the first solder composition. As such, improved interconnect formation can be obtained, even when substrate 310 has an undulating surface, similar to the embodiment described in FIGS. 2A-2C.

As shown in FIG. 3, the second interconnects 312B are distributed throughout the bump field. That is, there may not be a particular pattern with respect to the placement of the second interconnects 312B. For example, second interconnects 312B may be placed towards a middle of the substrate 310, along an edge of the substrate 310, proximate a corner of the substrate 310, or any other location where a localized depression is formed. The remainder of the bump field may be populated with the first interconnects 312A.

In the embodiments described herein, bump fields with a first interconnect type and a second interconnect type are envisioned. However, embodiments are not limited to two different interconnect types. For example, three or more interconnect types may be used in some embodiments as well. In such situations, three different solder compositions with three different melting temperatures may be provided. In such an embodiment, the lowest melting point solder may be positioned at the deepest recesses, a middle melting point solder may be positioned at intermediate recesses, and the highest melting point solder may be positioned at other locations.

Further, while embodiments described herein focus on interconnects with different melting temperatures which result from varying material compositions, embodiments are not limited to such differences. In other embodiments, the structure of the interconnects may also be varied. For example, a first interconnect may comprise substantially all solder, and a second interconnect may comprise a solder around a non-melting (at typical reflow temperatures) core (e.g., a copper core). Additionally, the volume of solder between a first interconnect and a second interconnect may be different in some embodiments.

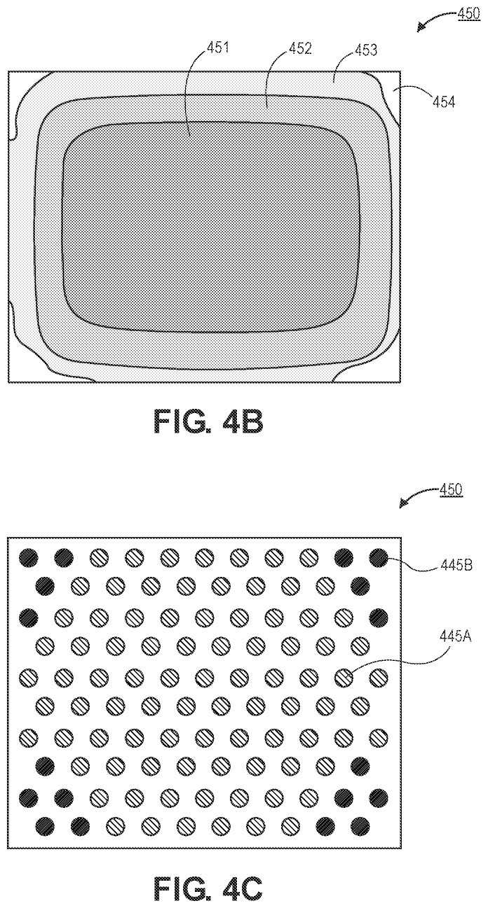

Referring now to FIGS. 4A-4C, a series of illustrations depicting a TCB process of a device 400 is shown, in accordance with an embodiment. As will be shown, the TCB process may result in a non-uniform heat flux. This may result in an incomplete reflow, which can lead to a defective device 400. Accordingly, two or more different solders can be used to enable complete reflow across an entire bump field.

Referring now to FIG. 4A, a cross-sectional illustration of the device 400 is shown, in accordance with an embodiment. In an embodiment, the device 400 comprises a pedestal 401 that opposes a heater 456 and a nozzle 457. A first substrate 440 is provided on the pedestal 401, and the nozzle 457 is coupled to a second substrate 450. In the particular embodiment shown in FIG. 4A, the first substrate 440 is a package substrate, and the second substrate 450 is a die. Though, other substrate types may be used for the first substrate 440 and the second substrate 450. In an embodiment, a bump field with interconnects 445 is provided between the first substrate 440 and the second substrate 450.

During a reflow process, the heater 456 provides thermal energy that is propagated to the interconnects 445. In an ideal scenario, the thermal energy is uniformly applied to all of the interconnects 445, and a uniform reflow and solidification process occurs. Unfortunately, such a process is unrealistic. In practice, a non-uniform heat distribution is provided. An example of such a heat distribution is shown in FIG. 4B.

Referring now to FIG. 4B, a plan view illustration of the bottom surface of the second substrate 450 is shown, in accordance with an embodiment. The different regions 451-454 illustrate regions of different thermal energy. For example, the center region 451 is the hottest region, and the corner regions 454 are the coolest regions. Region 452 is cooler than region 451, and region 453 is cooler than region 452, but hotter than region 454. As can be appreciated, the non-uniform heat distribution makes the reflow process more complex. For example, at a reflow setting that will melt the center interconnects, the edge and corner interconnects may remain solid.

One approach to solving such an issue is to increase the thermal energy outputted by the heater 456. While this may raise the temperature at the corners to enable reflow, the increased temperature also impacts warpage considerations. At higher temperatures, the substrates 440 and 450 undergo more extreme warpage, which can negatively impact interconnect performance and yield.

An alternative embodiment is shown in FIG. 4C. FIG. 4C is a plan view illustration of the second substrate 450 that depicts a hybrid bump field, in accordance with an embodiment. As shown, the hybrid bump field may include first interconnects 445A and second interconnects 445B. In an embodiment, the second interconnects 445B may be positioned proximate to areas of lower heat flux (e.g., as shown in FIG. 4B). Accordingly, second interconnects 445B may be positioned at corners of the bump field that are proximate to the corners of the substrate 450. That is, the second interconnects 445B may generally overlap the low energy corner regions 454 in FIG. 4B.

In an embodiment, the first interconnects 445A may comprise a first solder composition with a first melting temperature, and the second interconnects 445B may comprise a second solder composition with a second melting temperature that is lower than the first melting temperature. For example, the first melting temperature may be approximately 300° C. or higher, and the second melting temperature may be approximately 300° C. or lower. The first interconnects 445A and the second interconnects 445B may be tin-based solders with any suitable alloying elements. For example, interconnects 445A and 445B may comprise one or more of tin, copper, nickel, iron, indium, antimony, bismuth, silver, gold, palladium, or platinum. In some embodiments, the first interconnect 445A and the second interconnect 445B may comprise the same elemental constituents with different alloying percentages. In other embodiments, the first interconnect 445A and the second interconnect 445B may comprise different elemental constituents.

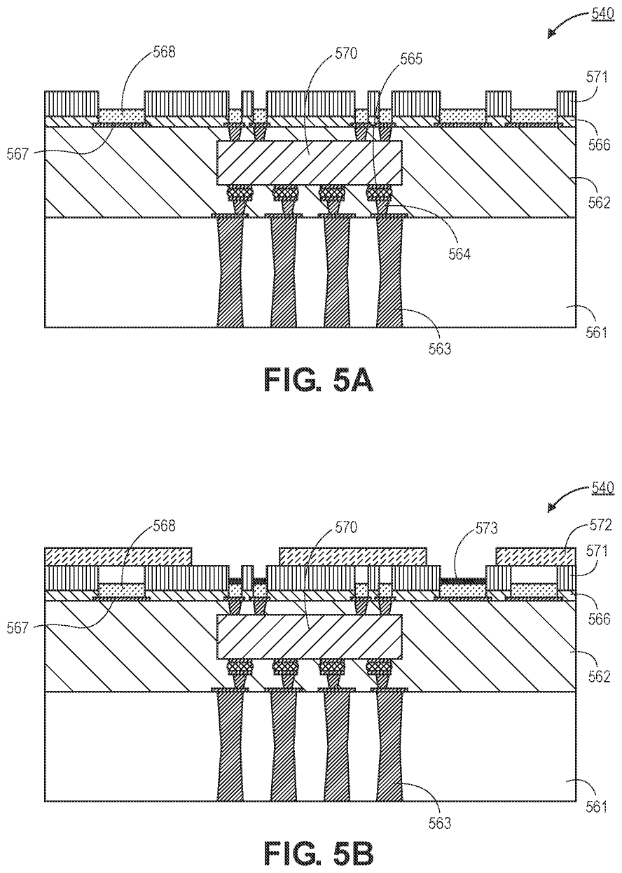

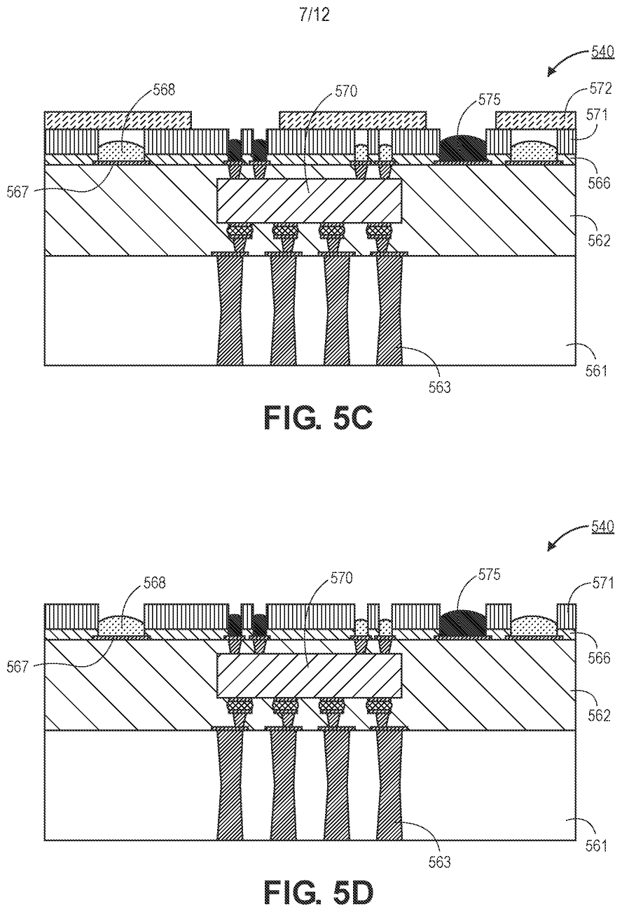

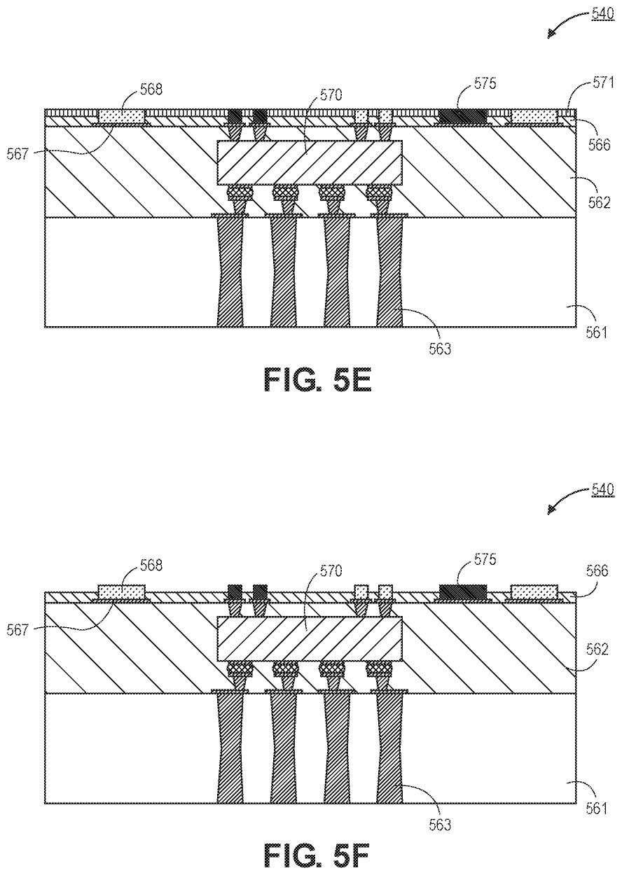

Referring now to FIGS. 5A-5F, a series of cross-sectional illustrations depicting a process for forming a substrate 540 with a hybrid bump field is shown, in accordance with an embodiment. In the particular embodiment shown in FIGS. 5A-5F, the substrate 540 is a package substrate. Though, other processing flows can be similarly constructed in order to form similar hybrid bump fields on substrates, such as, but not limited to, bridge dies, boards, dies, or the like.

Referring now to FIG. 5A, a portion of a package substrate 540 is shown, in accordance with an embodiment. In an embodiment, the package substrate 540 comprises a core 561 and buildup layers 562 over and/or under the core 561. In the illustrated embodiment, the structure of the package substrate 540 under the core is omitted for simplicity. Though, those skilled in the art will appreciated that buildup layers, electrical routing, and the like may be provided below the core 561. The core 561 may be an organic core in some embodiments. For example, the core 561 may comprise an organic polymer material with (or without) fiber reinforcement (such as glass fibers). In other embodiments, the core 561 may be a glass core 561.

The glass core 561 may be substantially all glass. The glass core 561 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 561 may be distinguished from, for example, the “prepreg” or “RF4” core of a Printed Circuit Board (PCB) substrate which typically comprises glass fibers embedded in a resinous organic material, such as an epoxy.

The glass core 561 may have any suitable dimensions. In a particular embodiment, the glass core 561 may have a thickness that is approximately 50 μm or greater. For example, the thickness of the glass core 561 may be between approximately 50 μm and approximately 1.4 mm. Though, smaller or larger thicknesses may also be used. The glass core 561 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 561 (from an overhead plan view) may be between approximately 10 mm×10 mm and approximately 250 mm×250 mm. In an embodiment, the glass core 561 may have a first side that is perpendicular or orthogonal to a second side. In a more general embodiment, the glass core 561 may comprise a rectangular prism volume with sections (e.g., vias) removed and filled with other materials (e.g., metal, etc.).

The glass core 561 may comprise a single monolithic layer of glass. In other embodiments, the glass core 561 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 561 may each have a thickness less than approximately 50 μm. For example, discrete layers of glass in the glass core 561 may have thicknesses between approximately 25 μm and approximately 50 μm. Though, discrete layers of glass may have larger or smaller thicknesses in some embodiments.

The glass core 561 may be any suitable glass formulation that has the necessary mechanical robustness and compatibility with semiconductor packaging manufacturing and assembly processes. For example, the glass core 561 may comprise aluminosilicate glass, borosilicate glass, alumino-borosilicate glass, silica, fused silica, or the like. In some embodiments, the glass core 561 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 561 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 561 may comprise at least 23 percent silicon (by weight) and at least 26 percent oxygen (by weight). In some embodiments, the glass core 561 may further comprise at least 5 percent aluminum (by weight).

In an embodiment, vias 563 may pass through a thickness of the core 561. The vias 561 may be formed with any suitable patterning and plating process. In some instances, the vias 561 may have tapered or sloped sidewalls. For example, in FIG. 5A the vias 561 have hourglass-shaped cross-sections. In an embodiment, the vias 561 may be coupled to an embedded bridge 570 through interconnects 565 and conductive routing 564 (e.g., pads, vias, traces, etc.) within the buildup layers 562. The bridge 570 may be a silicon die or the like that provides high density routing between chiplets (not shown) that are added above the package substrate 540 in a subsequent processing operation.

In an embodiment, pads 567 may be provided at a top surface of the buildup layers 562. The pads 567 may be covered by a solder resist 566 that includes openings to expose portions of the pads 562. In an embodiment, a first resist layer 571 may be provided over the solder resist 566. The first resist layer 571 may also have openings that expose the pads 567. The openings in the solder resist 566 may be aligned with openings in the first resist layer 571. The openings may be at least partially filled with a first solder 568.

Referring now to FIG. 5B, a cross-sectional illustration of the package substrate 540 after a second resist layer 572 is applied over the first resist layer 571 is shown, in accordance with an embodiment. The second resist layer 572 may cover some of the first solder 568. For example, from left to right, the first, fourth, fifth, and seventh instances of the first solder 568 are covered by the second resist layer 572. Openings in the second resist layer 572 expose the second, third, and sixth instances of the first solder 568. In an embodiment, the exposed locations are augmented by providing a dopant 573 over the first solder 568. The dopant 573 may include any metal element or elements that can result in a decrease in the melting temperature of the first solder 568. For example, the dopant 573 may comprise one or more of silver, bismuth, indium, zinc, or the like.

In an embodiment, the locations where the first solder 568 is augmented may be determined using various processes, such as those described herein. For example, the augmented locations may be in regions where the package substrate 540 has a localized depression. In other embodiments, the augmented locations may be in regions where the heat transfer is lower, and a lower melting point is desirable to enable full reflow.

Referring now to FIG. 5C, a cross-sectional illustration of the package substrate 540 after a reflow is shown, in accordance with an embodiment. As shown, the augmented regions result in the first solder 568 and the dopant 573 mixing together in order to form a second solder 575. The second solder 575 may have a different material composition than the first solder 568 due to the presence of the dopant 573. Further, the second solder 575 may have a lower melting temperature than the first solder 568. The addition of the dopant 573 may also result in the standoff height of the second solder 575 being larger than a standoff height of the first solder 568.

Referring now to FIG. 5D, a cross-sectional illustration of the package substrate 540 after the second resist 572 is removed is shown, in accordance with an embodiment. In an embodiment, the second resist 572 may be removed with a resist stripping process, or the like. In other embodiments, the second resist 572 may remain and be removed with the processing shown in FIG. 5E.

Referring now to FIG. 5E, a cross-sectional illustration of the package substrate 540 after a planarization process is shown, in accordance with an embodiment. In an embodiment, a fly-cutting process, a polishing process (e.g., chemical mechanical polishing (CMP)), or the like may be used in order to equalize the standoff heights of the first solder 568 and the second solder 575. The presence of the first resist 571 may prevent the smearing of the solders 568 and 575 during the planarization process.

Referring now to FIG. 5F, a cross-sectional illustration of the package substrate 540 after the first resist 571 is removed is shown, in accordance with an embodiment. In an embodiment, the first resist 571 may be removed with a resist stripping process, an etching process, or the like. Accordingly, portions of the first solder 568 and the second solder 575 extend up past the solder resist 566 with a substantially uniform standoff height (e.g., within approximately 5 μm of each other).

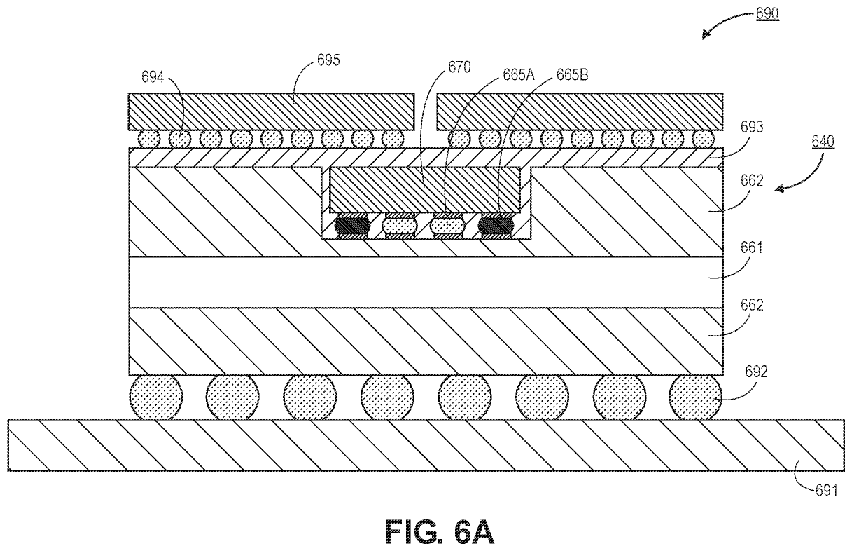

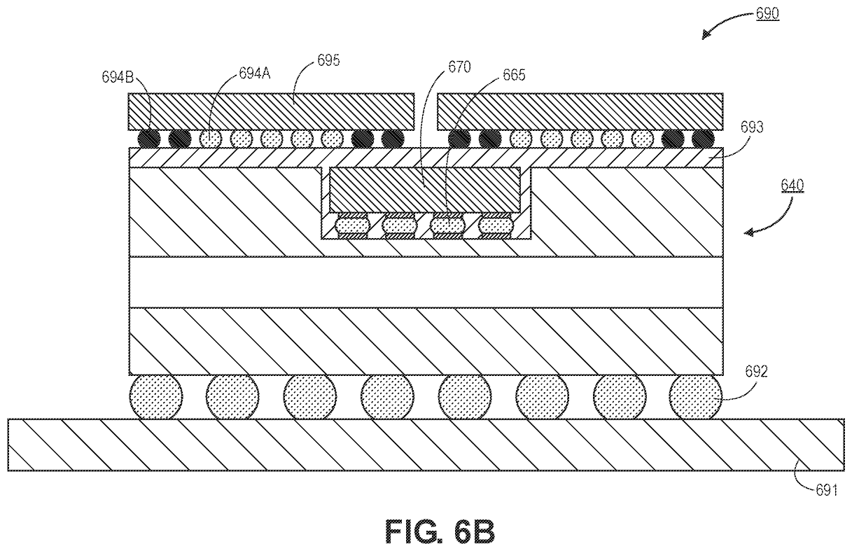

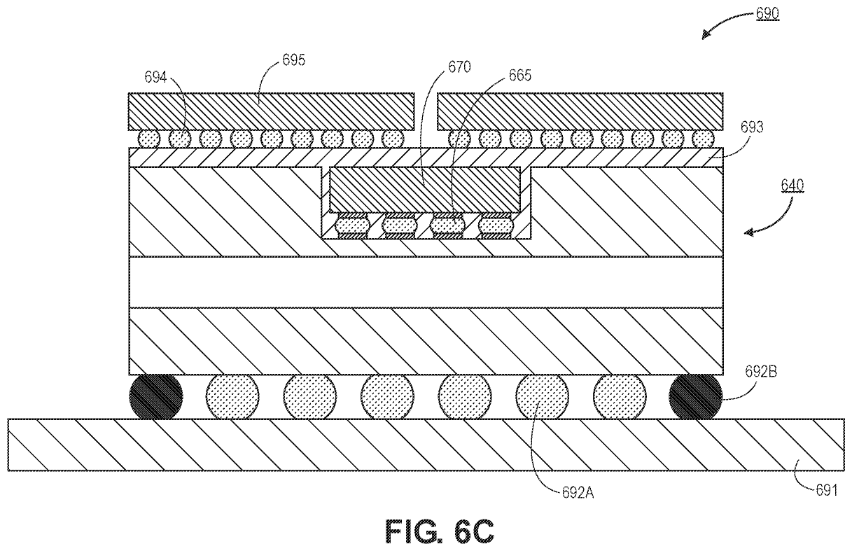

Referring now to FIGS. 6A-6C, a series of cross-sectional illustrations depicting electronic systems 690 with various architectures is shown, in accordance with an embodiment. The electronic systems 690 depict different locations where hybrid bump fields can be used to improve interconnect performance. While three different locations are shown in FIGS. 6A-6C, it is to be appreciated that any of the locations can be combined with each other in order to provide different embodiments then what are shown herein.

Referring now to FIG. 6A, a cross-sectional illustration of an electronic system 690 is shown, in accordance with an embodiment. In an embodiment, the electronic system 690 comprises a board 691. The board 691 may be a printed circuit board (PCB), a motherboard, or the like. In an embodiment, the board 691 is coupled to a package substrate 640 by interconnects 692. The interconnects 692 may be SLIs, such as solder bumps, sockets, or the like.

In an embodiment, the package substrate 640 may comprise a core 661 with buildup layers 662 above and/or below the core 661. The core 661 may be a glass core or an organic core. In an embodiment, a bridge 670 is positioned in a cavity in the top buildup layers 662. The bridge 670 may include bottom interconnects 665 that couple the bridge 670 to the package substrate 640. The interconnects 665 may allow for power or signals to pass vertically through the bridge 670 (e.g., through vias (not shown) in the bridge 670). In an embodiment, the interconnects 665 may be part of a hybrid bump field. For example, the interconnects 665 may include first interconnects 665A and second interconnects 665B. The first interconnects 665A may have a different composition than the second interconnects 665B. For example, the first interconnects 665A may have a higher melting temperature than the second interconnects 665B.

In an embodiment, an underfill 693 may surround the bridge 670 and cover a surface of the package substrate 640. Interconnects 694 may couple the package substrate 640 to overlying dies 695. The interconnects 694 may be any suitable FLI structure, such as solder balls, copper bumps, hybrid bonding interfaces, or the like. The dies 695 may be communicatively coupled together by the bridge 670. In an embodiment, the dies 695 may include any type of die, such as, but not limited to, a central processing unit (CPU), a graphics processing unit (GPU), an XPU, a communications die, a memory die, or the like.

Referring now to FIG. 6B, a cross-sectional illustration of an electronic system 690 is shown, in accordance with a different embodiment. The electronic system 690 in FIG. 6B may be similar to the electronic system 690 in FIG. 6A, with the exception of the interconnects 694 and 665. Instead of interconnects 665 being a hybrid bump field, a single type of interconnect is used. Additionally, a hybrid bump field is used for the interconnects 694. As such, the interconnects 694 include first interconnects 694A and second interconnects 694B. The first interconnects 694A may have a different material composition than the second interconnects 694B. For example, a melting temperature of the first interconnects 694A may be different than a melting temperature of the second interconnects 694B.

Referring now to FIG. 6C, a cross-sectional illustration of an electronic system 690 is shown, in accordance with a different embodiment. The electronics system 690 in FIG. 6C may be similar to the electronic system 690 in FIG. 6A, with the exception of the interconnects 692 and 665. Instead of interconnects 665 being a hybrid bump field, a single type of interconnect is used. Additionally, the interconnects 692 may include a hybrid bump field that includes first interconnects 692A and second interconnects 692B. The first interconnects 692A may have a different material composition than the second interconnects 692B. For example, a melting temperature of the first interconnects 692A may be different than a melting temperature of the second interconnects 692B.

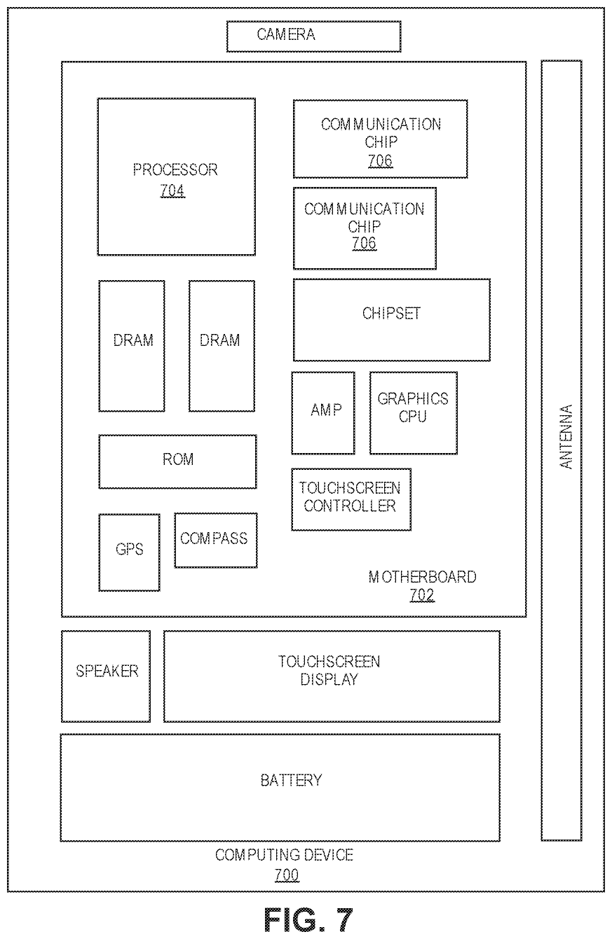

FIG. 7 illustrates a computing device 700 in accordance with one implementation of the disclosure. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the disclosure, the integrated circuit die of the processor may be part of an electronic package that includes a hybrid bump field between a pair of substrates that includes at least a first interconnect with a first melting temperature and a second interconnect with a second melting temperature that is lower than the first melting temperature, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the disclosure, the integrated circuit die of the communication chip may be part of an electronic package that includes a hybrid bump field between a pair of substrates that includes at least a first interconnect with a first melting temperature and a second interconnect with a second melting temperature that is lower than the first melting temperature, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a first substrate; a second substrate over the first substrate; and an array of interconnects between the first substrate and the second substrate, wherein the array of interconnects comprises: a first interconnect with a first material composition; and a second interconnect with a second material composition that is different than the first material composition.

Example 2: the apparatus of Example 1, wherein the first interconnect has a first melting point and the second interconnect has a second melting point that is lower than the first melting point.

Example 3: the apparatus of Example 2, wherein the first melting point is approximately 300° C. or higher, and the second melting point is approximately 300° C. or lower.

Example 4: the apparatus of Examples 1-3, wherein the array of interconnects comprises a rectangular array, and wherein the second interconnect is positioned at a corner of the rectangular array.

Example 5: the apparatus of Examples 1-4, wherein the first interconnect has a first height and the second interconnect has a second height, wherein the second height is greater than the first height.

Example 6: the apparatus of Examples 1-5, wherein the first substrate is a package substrate and the second substrate is a die.

Example 7: the apparatus of Example 6, wherein the die is embedded in the package substrate.

Example 8: the apparatus of Examples 1-7, wherein the first substrate is a board and the second substrate is a package substrate.

Example 9: the apparatus of Examples 1-8, wherein the first substrate is a package substrate that comprises a core with a rectangular prism glass volume.

Example 10: the apparatus of Examples 1-9, wherein the first material composition comprises one or more of tin, copper, nickel, iron, indium, antimony, bismuth, silver, gold, palladium, or platinum.

Example 11: an apparatus, comprising: a package substrate; a cavity in the package substrate, wherein the cavity has a bottom surface; a die at least partially in the cavity, and wherein the die is coupled to the bottom surface by first interconnects with a first material composition and second interconnects with a second material composition that is different than the first material composition.

Example 12: the apparatus of Example 11, wherein a number of first interconnects is fewer than a number of second interconnects.

Example 13: the apparatus of Example 11 or Example 12, wherein the first interconnects are proximate to corners of the die.

Example 14: the apparatus of Examples 11-13, wherein the first interconnects have a first height that is greater than a second height of the second interconnects.

Example 15: the apparatus of Examples 11-14, wherein the package substrate comprises a core, and wherein the core is glass with a rectangular prism shape.

Example 16: the apparatus of Examples 11-15, wherein the die is a bridge die, and wherein a second die and a third die are coupled together through the bridge die.

Example 17: an apparatus, comprising: a board; a package substrate over the board, wherein a first array of interconnects couple the package substrate to the board, wherein the first array comprises a first solder and a second solder; a die over the package substrate, wherein a second array of interconnects couple the die to the package substrate, wherein the second array comprises a third solder and a fourth solder; and wherein the first solder is different than the second solder, the third solder is different than the fourth solder, or both the first solder and second solder are different and the third solder and the fourth solder are different.

Example 18: the apparatus of Example 17, wherein the first solder is proximate to corners of the first array, and wherein the third solder is proximate to corners of the second array.

Example 19: the apparatus of Example 17 or Example 18, wherein the first solder has a lower melting temperature than the second solder, or wherein the third solder has a lower melting temperature than the fourth solder.

Example 20: the apparatus of Examples 17-19, wherein the apparatus is part of a personal computer, a server, a mobile device, a tablet, or an automobile.

What is claimed is:

1. An apparatus, comprising:
a first substrate;
a second substrate over the first substrate; and
an array of interconnects between the first substrate and the second substrate, wherein the array of interconnects comprises:
a first interconnect with a first material composition; and
a second interconnect with a second material composition that is different than the first material composition.

2. The apparatus of claim 1, wherein the first interconnect has a first melting point and the second interconnect has a second melting point that is lower than the first melting point.

3. The apparatus of claim 2, wherein the first melting point is approximately 300° C. or higher, and the second melting point is approximately 300° C. or lower.

4. The apparatus of claim 1, wherein the array of interconnects comprises a rectangular array, and wherein the second interconnect is positioned at a corner of the rectangular array.

5. The apparatus of claim 1, wherein the first interconnect has a first height and the second interconnect has a second height, wherein the second height is greater than the first height.

6. The apparatus of claim 1, wherein the first substrate is a package substrate and the second substrate is a die.

7. The apparatus of claim 6, wherein the die is embedded in the package substrate.

8. The apparatus of claim 1, wherein the first substrate is a board and the second substrate is a package substrate.

9. The apparatus of claim 1, wherein the first substrate is a package substrate that comprises a core with a rectangular prism glass volume.

10. The apparatus of claim 1, wherein the first material composition comprises one or more of tin, copper, nickel, iron, indium, antimony, bismuth, silver, gold, palladium, or platinum.

11. An apparatus, comprising:
a package substrate;
a cavity in the package substrate, wherein the cavity has a bottom surface; and
a die at least partially in the cavity, and wherein the die is coupled to the bottom surface by first interconnects with a first material composition and second interconnects with a second material composition that is different than the first material composition.

12. The apparatus of claim 11, wherein a number of first interconnects is fewer than a number of second interconnects.

13. The apparatus of claim 11, wherein the first interconnects are proximate to corners of the die.

14. The apparatus of claim 11, wherein the first interconnects have a first height that is greater than a second height of the second interconnects.

15. The apparatus of claim 11, wherein the package substrate comprises a core, and wherein the core is glass with a rectangular prism shape.

16. The apparatus of claim 11, wherein the die is a bridge die, and wherein a second die and a third die are coupled together through the bridge die.

17. An apparatus, comprising:
a board;
a package substrate over the board, wherein a first array of interconnects couple the package substrate to the board, wherein the first array comprises a first solder and a second solder;
a die over the package substrate, wherein a second array of interconnects couple the die to the package substrate, wherein the second array comprises a third solder and a fourth solder; and
wherein the first solder is different than the second solder, the third solder is different than the fourth solder, or both the first solder and second solder are different and the third solder and the fourth solder are different.

18. The apparatus of claim 17, wherein the first solder is proximate to corners of the first array, and wherein the third solder is proximate to corners of the second array.

19. The apparatus of claim 17, wherein the first solder has a lower melting temperature than the second solder, or wherein the third solder has a lower melting temperature than the fourth solder.

20. The apparatus of claim 17, wherein the apparatus is part of a personal computer, a server, a mobile device, a tablet, or an automobile.
